(19) United States
(12) Patent Application Publication
(10) Pub. No.: US 2025/0217534 A1
(43) Pub. Date: Jul. 3, 2025

(54) Modular System for Producing at Least Two Design Variants of a Storage Housing for a Motor Vehicle and Method

(71) Applicant: Bayerische Motoren Werke Aktiengesellschaft, Muenchen (DE)

(72) Inventor: Matthias STANGL, Friedberg (DE)

(21) Appl. No.: 18/852,588

(22) PCT Filed: May 4, 2023
(86) PCT No.: PCT/EP2023/061834

§ 371 Date: Sep. 30, 2024

(30) Foreign Application Priority Data
May 30, 2022 (DE) 10 2022 113 543.8

(51) Int. Cl. G06F 30/15

(52) U.S. Cl. CPC G06F 30/15

(57) ABSTRACT

A modular system for producing at least two design variants of a storage housing for an energy store for a motor vehicle. The modular system comprises a housing element and a support structure, said housing comprising a housing element which at least partially delimits a receiving space of the storage housing, for receiving at least one storage medium, and two support structures formed separately from the housing element and different from each other, via which the storage housing is to be held on a structure of the motor vehicle. A first design variant of the storage housing has the housing element and a first of the support structures, which in the first design variant is connected to the housing element. The second design variant of the storage housing has the housing element and the second support structure, which in the second design variant is connected to the housing element.

### BACKGROUND AND SUMMARY

This disclosure relates to a modular system for producing at least two design variants of a storage housing which has a housing element and a carrier structure for an energy store for a motor vehicle. Furthermore, the disclosure relates to a method for producing at least two design variants of a storage housing which has a housing element and a carrier structure for an energy store for a motor vehicle.

DE 10 2020 003 433 B3 discloses a body carrier structure for a vehicle having two side sills which are spaced apart from each other in the transverse vehicle direction and which each have a hollow space which is delimited outward in the transverse vehicle direction by way of an outer wall, inward in the transverse vehicle direction by an inner wall, upward in the vertical vehicle direction by an upper flange and downward in the vertical vehicle direction by way of a lower flange of the respective side sill and in which at least one reinforcement element which is configured separately from the respective side sill is arranged. The body carrier structure has a base which is arranged between the side sills and which is connected to the side sills and an energy store which is arranged below the base in order to store electrical energy and/or a propellant for driving the vehicle.

An object of the disclosure is to provide a modular system for producing at least two design variants of a storage housing which has a housing element and a carrier structure for an energy store for a motor vehicle and a method for producing at least two design variants of a storage housing which has a housing element and a carrier structure for an electrical energy store for a motor vehicle so that different design variants of the storage housing can be produced in a particularly non-complex manner and in accordance with requirements.

A first aspect of the disclosure relates to a modular system for producing at least two, in particular mutually different design variants of a storage housing which has a housing element and a carrier structure for an energy store for a motor vehicle. The motor vehicle is preferably in the form of an automobile, in particular a passenger vehicle. For example, the motor vehicle is in the form of a motor vehicle which can be electrically driven, in particular a motor vehicle which can be driven in a purely electrical manner. This means that the motor vehicle may be in the form of a battery-electric vehicle or a hybrid vehicle. For example, the motor vehicle has at least one electric machine by way of which the motor vehicle can be driven.

For example, the energy store is in the form of an electrical energy store, in particular a battery or an accumulator. The electrical energy store may be understood to be in particular an energy store which is configured to store electrical energy. By way of the electrical energy store the electric machine of the motor vehicle can, for example, be supplied with electrical energy which is in particular stored in the electrical energy store in order to drive the motor vehicle.

In order to be able to produce a particularly high level of electrical power for electrical, in particular purely electrical driving of the motor vehicle, the electrical energy store may have an electrical voltage, in particular an electrical operating or nominal voltage, which is preferably greater than 50 Volts, in particular above 60 Volts and preferably several hundred Volts. Accordingly, the electrical energy store may be in the form of a high-voltage component.

Alternatively, the energy store can be configured to store at least one fuel. This means that the energy store may, for example, be in the form of a tank. For example, the fuel is an electrochemical fuel, in particular hydrogen. For example, the motor vehicle has a fuel cell by way of which the electrochemical fuel can be converted into electrical energy. Consequently, for example, the electric machine can be supplied with the electrical energy for driving the motor vehicle by way of the fuel cell. Alternatively, for example, the fuel is a chemical fuel, in particular a propellant. For example, the motor vehicle has an internal combustion engine by way of which or in which the chemical fuel or the propellant can be burnt. The motor vehicle can thereby be driven, for example, by the internal combustion engine. For example, the chemical fuel or the propellant is hydrogen.

Preferably, the energy store has the storage housing in the completely produced state thereof. For example, a first of the design variants is installed or used in a first variant of the motor vehicle, wherein, for example, the second of the design variants is installed or used in a second variant of the motor vehicle. The respective variant may be understood to be in particular a respective series of the motor vehicle. For example, the variants of the motor vehicle differ with respect to their equipment, in particular their special equipment. Alternatively or additionally, the variants of the motor vehicle may be different vehicle types of the motor vehicle. Alternatively or additionally, the variants of the motor vehicle may, for example, differ from each other in terms of their respective vehicle weights. Preferably, the motor vehicle comprises in its completely produced state the energy store, in particular the storage housing. The energy store may in particular be referred to as a storage device.

The modular system has a housing element which particularly includes all the design variants and which at least partially, in particular completely delimits a receiving space, which is provided to receive, in particular to arrange, at least one storage medium, of the storage housing. In other words, the receiving space is at least partially, in particular completely surrounded or covered by the housing element, wherein the at least one storage medium can be received or arranged in the receiving space.

The fact that the housing portion includes all the design variants may in particular be understood to mean that both the first design variant and the second design variant have the same, in particular structurally identical housing element. Consequently, the housing element in the first and second design variant is provided to include all the design variants. This means that the housing element can be used or is used both for the first design variant and for the second design variant. Again, in other words, in the completely produced state of the design variants, the housing elements of the design variants are the same, in particular structurally identical or identical.

Particularly when the energy store is in the form of the electrical energy store, the storage medium may be in the form of an in particular electrical storage element. The storage medium may in particular be understood to be an in particular electrical or electrochemical, in particular active, cell material. The storage element is, for, example, an in particular electrical or electrochemical storage cell. The storage cell may in particular be understood to be a battery cell. A large number of storage cells can preferably be arranged or received in the receiving space. For example, there can be arranged in the receiving space at least one storage module which comprises a plurality of the storage cells. In the completely produced state of the electrical energy store, the at least one storage element, in particular the at least one storage cell, is preferably received or arranged in the receiving space.

Particularly when the energy store is configured to store the fuel, the housing element is, for example, in the form of a wall of the tank. Consequently, the housing element, in particular the tank, or the receiving space may be filled with the storage element which is in the form of fuel.

The storage medium may be part of the energy store or the storage medium may not be part of the energy store. This means that the energy store in its completely produced state may include the storage medium or that the energy store in its completely produced state may not include the storage medium. Particularly when the energy store is in the form of an electrical energy store, the storage medium, in particular the storage element or the storage cell, is preferably part of the electrical energy store.

The modular system has at least two carrier structures which are in particular specific to the design variant and which are configured separately from the housing element and are different from each other and via which the storage housing, in particular the energy store, is intended to be retained on a structure of the motor vehicle. In other words, the respective carrier structure has at least one connection location via which the storage housing, in particular the energy store, can be secured to the structure, in particular to a base element, for example, a main base, of the structure or the motor vehicle.

A structure may in particular be understood to be a shell of the motor vehicle. For example, the structure is in the form of an in particular self-supporting body of the motor vehicle.

The carrier structure may in particular be understood to be a respective portion of the storage housing, wherein a stability, in particular a strength and/or a rigidity of the storage housing, is at least substantially brought about by the carrier structure. This means that the carrier structure contributes more to an overall strength or overall rigidity of the storage housing than the housing element. For example, there may be provision for the respective carrier structure to contribute to a stability, in particular a rigidity and/or strength, of a body of the motor vehicle. This means that the energy store which has the storage housing in addition to providing drive energy can also bring about a carrier function for the motor vehicle, in particular the body of the motor vehicle. Consequently, the storage housing has, for example, on the one hand, the housing element in order to receive the storage medium, in particular the storage cell, and, on the other hand, the storage housing may have the carrier structure in order to provide a structural contribution to the overall vehicle function, with particular regard to the stability. For example, the housing element is provided to comply with sealing requirements of the energy store. This means that a sealing of the energy store, in particular the receiving space, for example, with respect to an environment of the energy store, can be brought about by the housing element.

In order to be able to produce different design variants of the storage housing in a particularly non-complex manner and in accordance with requirements, there is provision for a first of the design variants of the storage housing to have the housing element which includes in particular all the design variants and an in particular design-variant-specific first one of the carrier structures which in the first design variant is connected to the housing element. In other words, the housing element and the first carrier structure are provided in the first design variant. This means that the housing element and the first carrier structure are used in the first design variant.

The second design variant of the storage housing has the housing element which includes in particular all the design variants and the in particular design-variant-specific second carrier structure which in the second design variant is connected to the housing element. In other words, the second carrier structure is provided in the second design variant. This means that the housing element and the second carrier structure are used in the second design variant.

The fact that the first carrier structure is specific to the design variant or that the first carrier structure is used in the first design variant may in particular be understood to mean that the first carrier structure with respect to both design variants is used exclusively in the first design variant, but not in the second design variant. This means that the design variant is preferably free from the first carrier structure. In other words, the second carrier structure is not or does not become provided in the second design variant.

The fact that the second carrier structure is specific to the design variant or that the second carrier structure is used in the second design variant may in particular be understood to mean that the second carrier structure with respect to the two design variants is used exclusively in the second design variant but not in the first design variant. This means that the first design variant is preferably free from the second carrier structure. In other words, the second carrier structure is not or does not become provided in the first design variant.

This means that the energy store, in particular the storage housing, in the completely produced state in the first design variant comprises the first carrier structure and is preferably free from the second carrier structure. In the same manner, there is preferably provision for the energy store, in particular the storage housing, in the second design variant to have the second carrier structure and to be free from the first carrier structure.

Consequently, the respective carrier structure may in particular be understood to be a vehicle-specific or vehicle-family-specific respective carrier structure.

The disclosure is based in particular on the following recognitions and considerations. An integration of the energy store in the motor vehicle may represent a multi-dimensional task. For example, motor vehicles, in particular within an architecture of the motor vehicles, may differ with regard to their requirements placed on the energy store, with particular regard to energy content and/or geometric and structural integration in the motor vehicle. In other words, different motor vehicles, in particular within an architecture of the motor vehicles, may place different demands on the energy store. These requirements may, for example, be of a geometric nature, with particular regard to a structural space of the energy store and structural nature. The geometric nature may, for example, be understood to be that the requirements relate to a wheel base and/or a width and/or a height of the motor vehicle. The structural nature may in particular be understood to be that the requirements relate to a vehicle weight and/or an electrical range, in particular purely electrical range, of the motor vehicle and/or an energy content of the energy store. Generally, there may be provision to produce motor vehicles which provide the same energy contents, but different structural spaces, in particular for the energy store.

Generally, there may be provision to configure a conventional storage housing in a manner specific to the design variant so that in particular the housing element and the carrier structure are in each case configured in a manner specific to the design variant. This means that the different variants, in particular structural space variations between the different motor vehicles, can be produced with different housing elements and different carrier structures. Consequently, with conventional motor vehicles, generally no modular implementation or no modular system for the storage housing may be provided.

The modular system according to the disclosure, depending on the selection of the carrier structure, that is to say, depending on which of the carrier structures is used, enables the storage housing or the energy store to be configured in accordance with requirements, in particular for the respective design variant. It is thereby possible for the storage housing or the energy store to be adapted to the different variants of the motor vehicle in accordance with requirements and in a particularly non-complex manner, in particular in an especially cost-effective manner. Consequently, for example, the variants of the vehicles with the same requirements in terms of energy content but different structural requirements can be provided with the housing element which is identical or which includes all design variants and differences in the structural requirements can be implemented or brought about by adapting the carrier structure, that is to say, by the respective design-variant-specific carrier structure. Consequently, the modular system which is referred to in particular as a module can be produced from the housing element and respective carrier structure, whereby in a particularly non-complex, in particular especially cost-effective manner, many different vehicle families can be produced. Furthermore, for example, a weight of the storage housing or the energy store in the respective design variant may be kept particularly low. This means that specific vehicle requirements can be implemented by way of the modular system according to the disclosure in a particularly cost-effective and particularly weight-saving manner. Furthermore, as a result of the modular system according to the disclosure, for example, energy content and sealing of the energy store, in particular components of the energy store, can be ensured.

For example, there is provision for the housing element and the respective carrier structure in the respective design variant to be joined in such a manner that all of the requirements placed on the energy store in the motor vehicle can be met only when the housing element and the respective carrier structure are joined or connected to each other.

Particularly when the energy store is secured to the base element or is arranged in the underfloor of the motor vehicle, body structures, for example, cross-members and/or longitudinal members, may compete with a structural space or around the structural space of the energy store. As a result of the fact that the storage housing has the housing element and the respective carrier structure which is formed separately from the housing element, the structural space of the body of the motor vehicle can be configured in a particularly advantageous manner, in particular can be kept particularly small. Particularly when structural functions of the vehicle are implemented both by the body structures and by the carrier structure of the energy store, the structural space of the body or the storage housing can be configured in a particularly advantageous manner, in particular can be kept particularly small.

In other words, an extremely extensive separation of a carrier function of the energy store or the storage housing from a requirement placed on energy content and sealing may be provided, wherein the separation can be brought about by dividing the storage housing into the housing element and the respective carrier structure, wherein the housing element and the respective carrier structure are joined together in the completed produced state of the storage housing. In particular, in this instance, by way of the modular system according to the disclosure, particularly large vehicle architectures can be produced, in which costs of the generally particularly expensive energy store can be kept particularly low or can be reduced.

In another embodiment, there is provision for the respective carrier structure to be in the form of a respective carrier frame. In other words, the respective carrier structure is in the form of a frame. This means that in the first design variant the first carrier structure is in the form of a first carrier frame, which is connected to the housing element in the first design variant, wherein in the second design variant the second carrier structure is in the form of a second carrier frame which is different from the first carrier frame and which is connected to the housing element in the second design variant. A stability, in particular a strength and/or a rigidity, of the respective carrier structure and consequently of the storage housing or the energy store can thereby be particularly increased.

The fact that the respective carrier structure is in the form of a respective carrier frame can in particular be understood to mean that the respective carrier structure in each case has two side portions which are spaced apart from each other and two transverse portions which are spaced apart from each other. The side portions and the transverse portions may be configured integrally with each other. Alternatively, the side portions and the transverse portions may be configured in each case separately from each other and connected to each other. The side portions may in particular be referred to as longitudinal portions.

In another embodiment, there is provision in the respective design variant for the housing element to be received in the respective carrier structure, in particular in the respective carrier frame. This means that in the first design variant the housing element is received in the first carrier structure, in particular in the first carrier frame and that in the second design variant the housing element is received in the second carrier structure, in particular in the second carrier frame. In other words, in the respective design variant the housing element is at least partially surrounded or covered by the respective carrier structure. Again, in other words, the respective carrier structure at least partially delimits a receiving region which is in particular different from the receiving space and in which the housing element can be arranged or can be received. The stability of the storage housing can thereby be particularly increased.

In another embodiment, there is provision for the housing element to comprise two housing portions which are configured separately from each other and which are connected to each other. In other words, the housing element may be configured in several parts or several pieces. The housing element can thereby, for example, be produced in a particularly non-complex, especially particularly cost-effective manner. Furthermore, the housing element or the receiving space may be kept particularly sealed by the two housing portions. For example, the receiving space is at least partially, in particular completely, delimited by the housing portions.

Preferably, there is provision for at least one of the housing portions to be in the form of a shell, in particular multiple shells, for example, two shells. In other words, at least one of the housing portions is configured with a shell structure, in particular a multiple-shell structure, for example, two-shell structure. The storage housing, in particular the housing portion, can thereby be produced in a particularly non-complex, especially particularly cost-effective manner. For example, both housing portions are in the form of a shell. In other words, the housing element may be configured with a multiple-shell structure, in particular two-shell structure, in particular metal sheet structure. The costs of the housing element can thereby be kept particularly low.

In another embodiment, there is provision for the housing element, in particular one of the housing portions, to have at least one transverse strut which extends in an installation position of the housing element in the transverse vehicle direction of the motor vehicle. In other words, a longitudinal extent direction of the transverse strut which is referred to in particular as the main extent direction in the installation position of the housing element or the storage housing in the motor vehicle extends parallel with the transverse vehicle direction of the motor vehicle. It is thereby possible for a stability, in particular a rigidity and/or a strength, of the housing element to be particularly increased. For example, a degree of inherent rigidity of the housing element can thereby be brought about.

In another embodiment, there is provision for the housing element, in particular one of the housing elements, to have at least one connection location, via which the housing element or the storage housing can be secured in particular directly to the structure, in particular the base element, of the motor vehicle. The connection location of the respective carrier frame may, in particular in order to differentiate, for example, be referred to as the first connection location and the connection location of the housing element may, for example, be referred to as the second connection location. In other words, the housing element is intended to be retained via the at least one connection location, in particular directly, on the structure of the motor vehicle. This means that in the completely produced state of the motor vehicle the housing element is connected via the second connection location, in particular directly, to the structure of the motor vehicle. A particularly secure connection of the storage housing or the housing element to the structure of the motor vehicle can thereby be brought about. Preferably, there is provision for the transverse strut to have the second connection location.

In another embodiment, there is provision in the respective design variant for the housing element and the respective carrier structure to be adhesively bonded to each other. This means that in the first design variant the housing element and the first carrier structure are adhesively bonded to each other and in the second design variant the housing element and the second carrier structure are adhesively bonded to each other. In other words, the housing element and the respective carrier structure are connected in each case by way of adhesion. The housing element and the respective carrier structure can thereby be connected to each other in a particularly secure, in particular especially resistant manner. In this instance, the stability of the storage housing can particularly be increased. Furthermore, the storage housing can be produced in a particularly non-complex, in particular especially cost-effective manner.

Alternatively or additionally, the housing element and the respective carrier structure may be or become connected to each other, for example, by way of screws and/or by way of rivets, in particular self-piercing rivets and/or by way of friction stir welding and/or by way of another preferably non-thermal joining method. In order to be able to connect the housing element and the respective carrier structure to each other in a particularly advantageous manner, a combination of adhesive-bonding and screwing may be provided. This means that the housing element and the respective carrier structure are or become connected to each other, in particular directly, by way of adhesive-bonding and by way of screws. Consequently, a combination of an adhesive connection and screw connection may be provided. The adhesive connection can thereby harden in a particularly advantageous, in particular especially non-complex and/or particularly secure manner. In particular, in this instance, by fixing the housing element and the respective carrier structure by way of the screw connection, a hardening time for hardening an adhesive which is provided for adhesive-bonding can be kept particularly low or the hardening time can be dispensed with.

In another embodiment, there is provision for a third design variant of the storage housing which is different from the design variants to have a second housing element which is different from the housing element and which at least partially delimits a second receiving space which is provided to receive or arrange the at least one storage medium and which is in particular different from the receiving space and one of the carrier structures to which the second housing element is connected in the third design variant.

This may in particular be understood to mean the following: the housing element which is in particular referred to as the first housing element has the receiving space which is referred to in particular as the first receiving space, wherein the second housing element has the second receiving space which is different from the first receiving space. The fact that the receiving spaces are different from each other may in particular be understood to mean that a respective volume which is provided to receive or arrange the at least one storage medium is in each case of a different size. In the third design variant, one of the carrier structures, for example, the first carrier structure, and the second housing element are used or provided. In this instance, in the third design variant preferably the other of the carrier structures, for example, the second carrier structure, and the first housing element are not provided, which means that the third design variant is preferably free from the other of the carrier structures, for example, the second carrier structure, and the first housing element. In the first and the second design variants, the first housing element is used or provided in each case. In this instance, in the first and the second design variant, the second housing element is preferably not used, which means that the first and the second design variants are preferably free from the second housing element in each case. This means that the first housing element with respect to the first and second design variants is configured or provided to include all design variants, wherein the housing elements with respect to the first and the third design variants or with respect to the second and the third design variants are configured or provided to be specific to the design variant. For example, the third design variant is or becomes provided for a third variant of the motor vehicle which is different from the first and the second variants. The storage housing can thereby be adapted in accordance with requirements in a particularly non-complex, in particular especially cost-effective manner, for the third variant of the motor vehicle. The third variant may in particular be understood to be a third series of the motor vehicle. In particular, in this instance using the modular system many different vehicle families can be configured in a particularly non-complex, in particular especially cost-effective manner with a manageable number of different housing elements. Costs and complexity of the motor vehicle production can thereby be kept particularly low.

A second aspect of the disclosure relates to a method for producing at least two design variants, which are in particular different from each other, of a storage housing which has a housing element and a carrier structure for an energy store for a motor vehicle. Advantages and advantageous embodiments of the first aspect of the disclosure are intended to be considered to be advantages and advantageous embodiments of the second aspect of the disclosure, and vice versa.

The method comprises the steps of:
providing a housing element which at least partially delimits a receiving space, which is provided to receive, in particular to arrange, at least one storage medium, of the storage housing and
providing two carrier structures which are configured separately from the housing element and which are different from each other and via which the storage housing is intended to be retained on a structure of the motor vehicle.

In other words, in a step of the method which is referred to in particular as the first step and in a step of the method which is referred to in particular as the second step, a first of the carrier structures and the second of the carrier structures are provided.

In order to be able to produce different design variants in accordance with requirements and in a particularly non-complex manner, there is provision in order to produce a first of the design variants of the storage housing for the housing element and the first carrier structure which in the first design variant is connected to the housing element to be provided, and in order to produce the second design variant of the storage housing for the housing element and the second carrier structure which in the second design variant is connected to the housing element to be provided.

Another aspect relates to the use of a modular system according to the first aspect of the disclosure, wherein the modular system is used in order to produce at least one of the design variants. Advantages and advantageous embodiments of the first and second aspects of the disclosure are intended to be considered to be advantages and advantageous embodiments of the additional aspect, and vice versa.

Other features of the disclosure will be appreciated from the claims, the Figures and the description of the Figures. The features and feature combinations mentioned above in the description and the features and feature combinations mentioned below in the description of the Figures and/or shown in the Figures alone can be used not only in the combination set out in each case, but also in other combinations or alone.

### BRIEF DESCRIPTION OF THE DRAWINGS

The disclosure will now be explained in greater detail with reference to a preferred exemplary embodiment and with reference to the drawings.

FIG. 1 shows a schematic illustration to illustrate a modular system according to the disclosure;

FIG. 2 shows a schematic plan view of a storage housing which can be produced in two design variants by way of a modular system according to the disclosure;

FIG. 3 shows a schematic, perspective view of a housing element and a carrier structure of the storage housing from FIG. 2;

FIG. 4 shows a schematic, perspective view of the carrier structure from FIG. 3;

FIG. 5 shows a schematic, partially sectioned view of the storage housing from FIG. 2;

FIG. 6 shows a schematic, partially sectioned view of the storage housing from FIG. 2; and,

FIG. 7 shows a schematic, partially sectioned view of the storage housing from FIG. 2.

In the Figures, identical or functionally identical elements are given the same reference numerals.

### DETAILED DESCRIPTION OF THE DRAWINGS

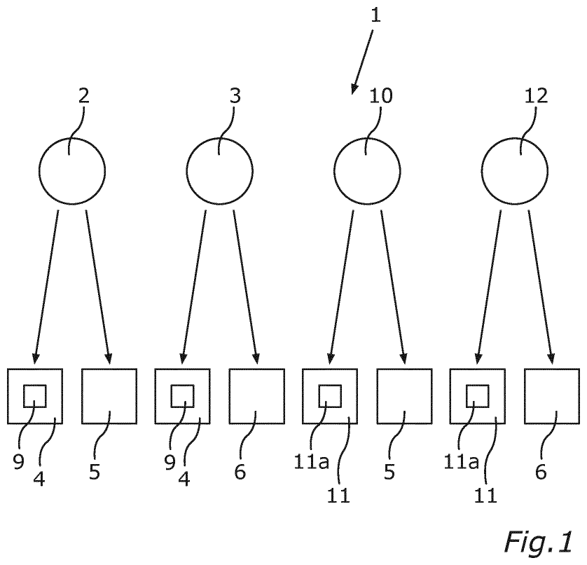

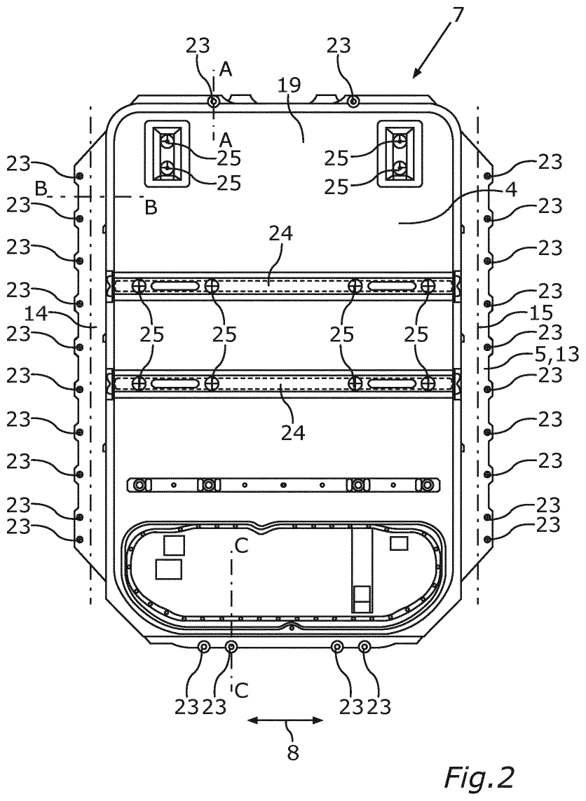

FIG. 1 shows a schematic illustration for illustrating a modular system 1 for producing at least two, in particular mutually different design variants 2, 3 of a storage housing 7 which has a housing element 4 and a carrier structure 5 for an in particular electrical energy store for a motor vehicle which can in particular be driven electrically. FIG. 2 shows the storage housing 7 as a schematic plan view.

The storage housing 7 has a housing element 4 which can in particular be described as a containment. The modular system 1 has two mutually different carrier structures 5, 6 which are configured separately from the housing element 5 and via which the storage housing 7 is in each case intended to be retained on a structure of the motor vehicle. FIG. 2 shows a first of the carrier structures 5 by way of example.

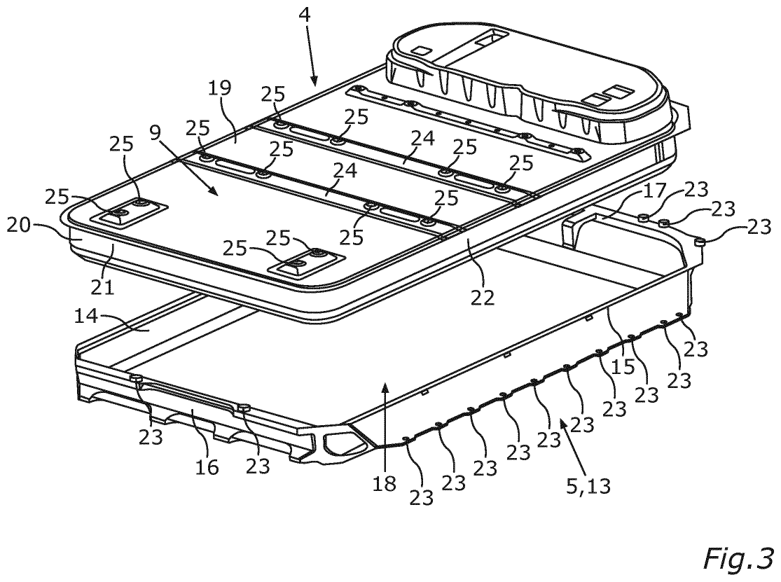

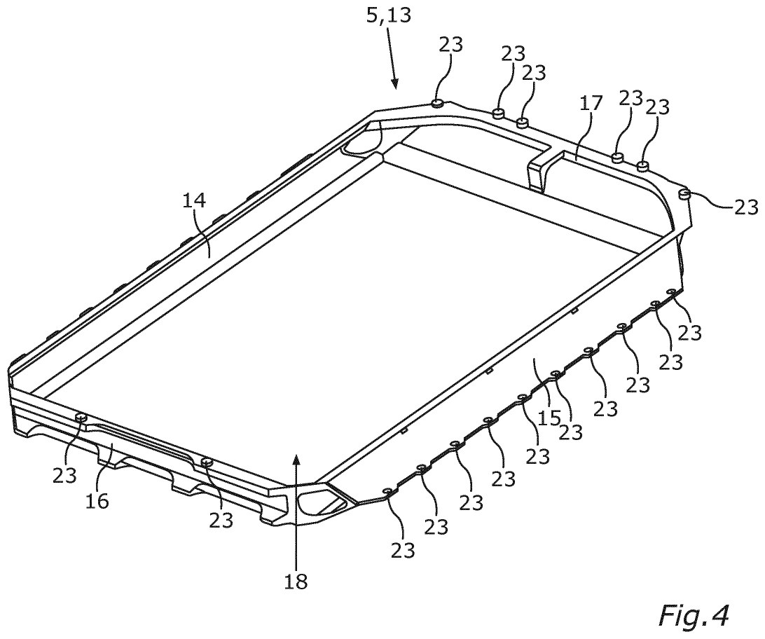

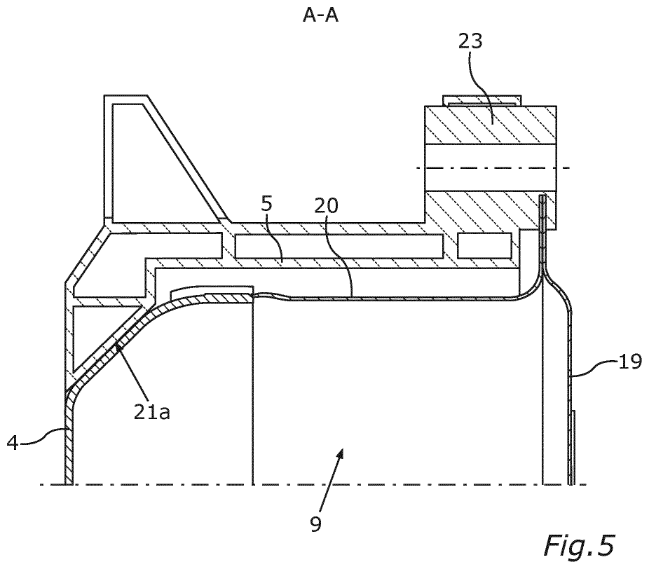

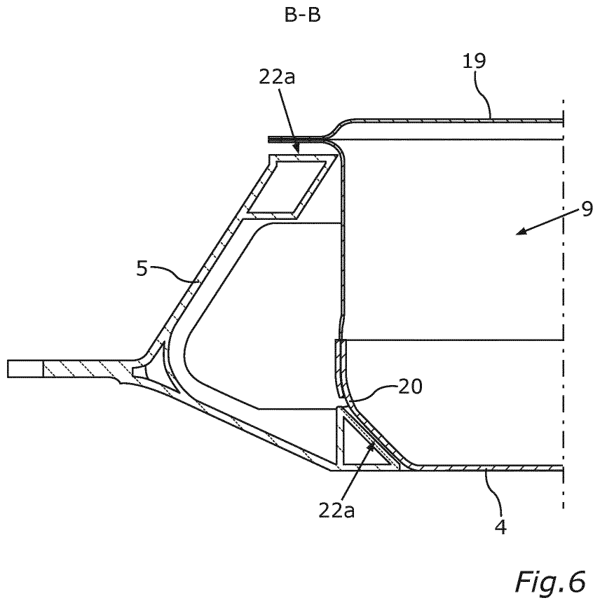

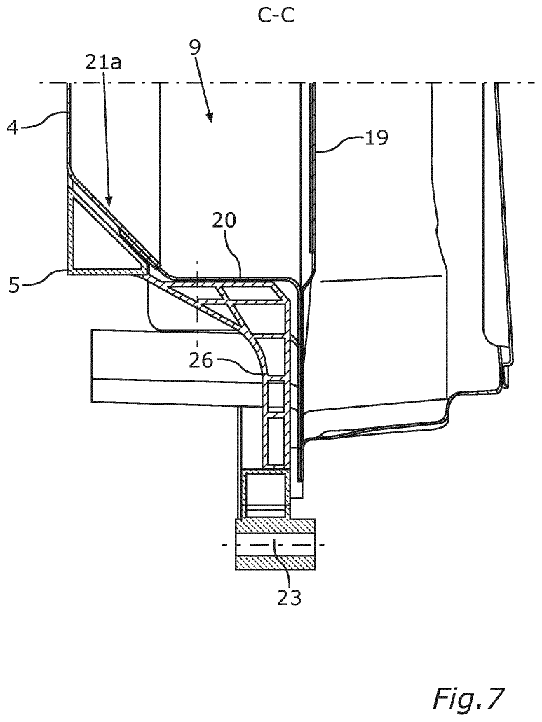

FIG. 3 shows the housing element 4 and the first carrier structure 5 as a schematic, perspective view, wherein the housing element 4 and the first carrier structure 5 in FIG. 3 are not in their installation position. This means that the storage housing 7 in FIG. 3 is not in its completely produced state. FIG. 4 shows the first carrier structure 5 as a schematic, perspective view. FIGS. 5 to 7 show the storage housing 7 as a schematic partially sectioned view in each case. In this instance, FIG. 5 shows a first section A-A which extends between section reference points A, which are depicted in FIG. 2. FIG. 6 shows a second section B-B which extends between section reference points B which are depicted in FIG. 2. FIG. 7 shows a third section C-C which extends between section reference points C which are depicted in FIG. 2.

The housing element 4 at least partially, in particular completely delimits a receiving space 9, which is produced for receiving, in particular for arranging at least one storage medium, of the storage housing 7. This means that the receiving space 9 is arranged inside the housing element 4.

In order to be able to produce the design variants 2, 3 in accordance with the requirements and in a particularly non-complex manner, there is provision for a first of the design variants 2 of the storage housing 7 to have the housing element 4 and the first carrier structure 5 which in the first design variant 3 is connected to the housing element 4. The second design variant 3 of the storage housing 7 has the housing element 4 and the second carrier structure 6 which in the second design variant 3 is connected to the housing element 4. This means that the housing element 4 with respect to the first and the second design variants 2, 3 is configured to extend over the installation space and that the respective carrier structure 5, 6 with respect to the first and second design variants 2, 3 is configured to be specific to the design variant. In the first design variant 2, consequently, the storage housing 7 is retained on the structure by the first carrier structure 5 and in the second design variant 3 the storage housing 7 is retained on the structure by the second carrier structure 6. It is thereby possible, for example, for two different variants of the motor vehicle, which have, for example, the same requirements with regard to an energy content of the energy store, for the same housing element 4 to be used, wherein by way of the respective, different carrier structures 5, 6 in the two design variants 2, 3 the storage housing 7 can be adapted as required for the two variants of the motor vehicle in each case with regard to geometric and/or structural requirements of the respective variants. The respective storage housing 7 or the respective variant of the motor vehicle can thereby be produced in a particularly non-complex, in particular especially cost-effective manner.

The modular system 1 can be used for a method for producing the at least two design variants 2, 3 of the storage housing. In the method, the housing element 4 and the carrier structures 5, 6 are provided, wherein in order to produce or during the production of the first design variant 2 of the storage housing 7 the housing element 4 and the first carrier structure 5, which in the first design variant 2 is connected to the housing element 4, are provided and in order to produce or during the production of the second design variant 3 of the storage housing 7 the housing element 4 and the second carrier structure 6, which in the second design variant 3 is connected to the housing element 4, are provided.

In another embodiment, a third design variant 10 of the storage housing 7 which is different from the design variants 2, 3 is provided. The third design variant 10 of the storage housing 7 has a second housing element 11 which is different from the housing element 4 which is in particular referred to as a first housing element 4 and which at least partially, in particular completely, delimits a second receiving space 11a which is provided to receive, in particular arrange the at least one storage medium. The third design variant 10 has one of the carrier structures 5, 6, for example, the first carrier structure 5, to which the second housing element 11 is connected in the third design variant 10. For example, the third design variant 10 is provided for a third variant of the motor vehicle. Consequently, the storage housing 7 can be adapted by way of the modular system 1 in a particularly non-complex, in particular especially cost-effective manner for the third variant of the motor vehicle, for example, with regard to the energy content of the energy store.

For example, there is provision for a fourth design variant 12 of the storage housing 7 which is different from the design variants 2, 3, 10 to have the second housing element 9 and the other of the carrier structures 5, 6, for example, the second carrier structure 6. This means that the second housing element 11 with respect to the third and fourth design variants 10, 12 is configured to include all the design variants. With respect to the first and the third design variants 2, 10 and/or with respect to the first and the fourth design variants 2, 12 and/or with respect to the second and the third design variants 3, 10 and/or with respect to the second and the fourth design variants 3, 12, the housing elements 4, 11 are configured in a manner specific to the design variant. For example, the first carrier structure 5 with respect to the first and third design variants 2, 10 is configured to include all the design variants. For example, the second carrier structure 6 with respect to the second and fourth design variants 3, 12 is configured to include all the design variants. For example, the first carrier structure 5 with respect to the first and third design variants 2, 10 is configured to include all the design variants. For example, the carrier structures 5, 6 are with respect to the first and the second design variants 2, 3 and/or with respect to the first and the fourth design variants 2, 12 and/or with respect to the second and the third design variants 3, 10 and/or with respect to the third and the fourth design variants 10, 12 configured to be specific to the design variant.

Preferably, there is provision for the respective carrier structure 5, 6 to be in the form of a respective carrier frame 13. This means that the respective carrier structure 5, 6 has, for example, in each case two longitudinal portions 14, 15 which are spaced apart from each other and in each case two transverse portions 16, 17 which are spaced apart from each other. This is shown in FIG. 4. The respective carrier structure 5, 6 can thereby be configured in a particularly stable manner. A stability of the storage housing 7 can thereby be particularly increased. For example, the longitudinal portions 14, 15 extend in the installation position of the storage housing 7 or the respective carrier structure 5, 6 in the motor vehicle in the longitudinal vehicle direction. For example, the transverse portions 16, 17 extend in the installation position of the storage housing 7 or the respective carrier structure 5, 6 in the motor vehicle in the transverse vehicle direction 8.

Preferably, there is provision in the respective design variant 2, 3, 10, 12 for the respective housing element 4, 11 to be received in the respective carrier structure 5, 6. In other words, the respective carrier structure 5, 6 delimits a respective receiving region 18 which is in particular different from the receiving spaces 9, 11a and in which the respective housing element 4, 11 can be arranged or can be received. For example, the respective housing element 4, 11 in the respective design variant 2, 3, 10, 12 is inserted into the respective carrier structure 5, 6, in particular into the receiving region 18 or the carrier frame 13.

In another embodiment, there is provision for the respective housing element 4, 11 to comprise in each case 2 housing portions 19, 20 which are configured separately from each other and which are connected to each other. Preferably, at least one of the housing portions 19, 20 is configured in a shell-like manner. For example, both housing portions 19, 20 are configured in a shell-like manner. A stability of the respective housing element 4, 11 can thereby be particularly increased. Furthermore, the respective housing element 4, 11 can be produced in a particularly cost-effective manner. For example, the respective housing element 4, 11, in particular the respective housing portion 19, 20 is in each case formed from a metal sheet. This can in particular be described as a sheet construction type. Alternatively, the respective housing element 4, 11 may be formed from plastics material. This means that the respective carrier structure 5, 6 may be configured to enable a combination of the respective carrier structure 5, 6 with the housing element 4, 11 which is formed from the plastics material. For example, the respective carrier structure 5, 6 is configured with a profile construction type, in particular aluminum profile construction type, or with a shell construction type, in particular steel shell construction type.

For example, the respective housing element 4, 11 and the respective carrier structure 5, 6 in the respective design variant 2, 3, 10, 12 is joined together by way of a non-thermal joining method. For example, in the respective design variant 2, 3, 10, 12 the respective housing element 4, 11 and the respective carrier structure 5, 6 are adhesively bonded to each other.

Alternatively, in the respective design variant 2, 3, 10, 12 the respective housing element 4, 11 and the respective carrier structure 5, 6 may, for example, be screwed to each other or connected to each other by way of riveting, in particular self-piercing riveting or by way of friction stir welding. FIG. 3 shows by way of example joining faces 21, 22 on which the respective housing element 4, 11 and the respective carrier structure 5, 6 can be joined together. Preferably, the respective joining faces 21, 22 are adhesive faces. Preferably, there is provision for the respective carrier structure 5, 6 and the respective housing element 4, 11 to be adhesively bonded and screwed to each other. The respective carrier structure 5, 6 and the respective housing element 4, 11 may thereby, for example, during a drying operation of an adhesive which is provided for adhesive bonding be fixed in a particularly secure manner.

FIGS. 5 to 7 show respective regions 21a, 22a which are in particular referred to as adhesive regions into or onto which adhesive can be introduced or applied in order to adhesively bond the respective housing element 4, 11 and the respective carrier structure 5, 6 to each other. For example, the regions 21a, 22a are in the form of respective adhesive flanges.

Preferably, there is provision for the respective carrier structure 5, 6 to have in each case at least one connection location 23 via which the storage housing 7 or the respective carrier structure 5, 6 can be secured to the structure of the motor vehicle, in particular to a base element of the structure. In the exemplary embodiment, there are provided a plurality of connection locations 23, via which the storage housing 7 or the respective carrier structure 5, 6 can be secured to the structure, in particular the base element, of the motor vehicle. For example, the base element is in the form of a main base of the structure. For example, the storage housing 7 can be screwed to the structure of the motor vehicle by way of the respective connection location 23. For example, the respective connection location 23 is in the form of a bush or of bush-like form. This can in particular be understood to mean that the respective connection location has a receiving bush which has a respective thread for receiving a screw element.

For example, there is provision in the respective design variant 2, 3, 10, 12 for the respective carrier structure 5, 6 and the respective housing element 4, 11 to bear in particular directly, in a planar, in particular extensive manner on each other. For example, there is provision for the respective carrier structure 5, 6 to produce or form in particular large, closed cross sections in a longitudinal direction and a transverse direction of the respective housing element 4, 11. As a result of these cross sections, in particular as a result of a connection of the cross sections with respect to the respective housing element 4, 11, for example, structural properties of the entire motor vehicle can particularly be improved. This means that, for example, a stability of the body of the motor vehicle can particularly be increased.

In another embodiment, there is provision for the respective housing element 4, 11 to have at least one transverse strut 24 which extends in the installation position of the respective housing element 4, 11 or of the storage housing 7 in the motor vehicle in the transverse vehicle direction 8 of the motor vehicle. In the exemplary embodiment shown in FIG. 2 and FIG. 3, the respective housing element 4, 11 has in each case two transverse struts 24 which extend in the installation position of the respective housing element 4, 11 in the motor vehicle in the transverse vehicle direction 8 of the motor vehicle. The stability of the respective housing element 4, 11 can thereby particularly be increased.

In another embodiment, there is provision for the respective housing element 4, 11 to have at least one connection location 25 which in particular differs from the respective connection location 23 and which is in particular referred to as a second connection location 25 and via which the respective housing element 4, 11 can be secured to the structure, in particular to the base element, of the motor vehicle. In the exemplary embodiment shown in FIG. 2 and FIG. 3, the respective housing element 4, 11 has a plurality of connection locations 25 via which the respective housing element 4, 11 can be secured to the structure, in particular to the base element of the motor vehicle. Preferably, at least one of the connection locations 25 is arranged at or on the respective transverse strut 24. The respective housing element 4, 11 can thereby be connected in a particularly safe or particularly secure manner to the structure of the motor vehicle.

As shown in FIG. 7, there is, for example, provision for the respective carrier structure 5, 6 to have in each case at least one extruded profile 26.

For example, there is provision for the storage housing 7 or the energy store in the installation position in the motor vehicle to be arranged in the vertical vehicle direction below the base element, in particular the main base. A structural space of the motor vehicle, in particular the body, can thereby be configured in a particularly advantageous manner, in particular can be kept particularly small.

For example, there is provision for the respective receiving space 9, 11a to be configured to receive at least one electronic calculation device. This means that in the completely produced state of the energy store the at least one electronic calculation device can be arranged in the respective receiving space 9, 11a. For example, the electronic calculation device is in the form of a control device. Preferably, the electronic calculation device is provided to operate or to control the energy store.

### LIST OF REFERENCE NUMERALS

1 Modular system
2 First design variant
3 Second design variant
4 First housing element
5 First carrier structure
6 Second carrier structure
7 Storage housing
8 Transverse vehicle direction
9 First receiving space
10 Third design variant
11 Second housing element
11a Second receiving space
12 Fourth design variant
13 Carrier frame
14 Longitudinal portion
15 Longitudinal portion
16 Transverse portion
17 Transverse portion
18 Receiving region
19 Housing portion
20 Housing portion
21 Joining face
21a Region
22 Joining face
22a Region
23 Connection location
24 Transverse strut
25 Connection location
26 Extruded profile
A Section reference point
B Section reference point
C Section reference point
A-A First step
A-B Second step
C-C Third step

1.-10. (canceled)

11. A modular system for producing at least two design variants of a storage housing, the modular system comprising:
a housing element and a carrier structure for an energy store for a motor vehicle, wherein the housing element at least partially delimits a receiving space of the storage housing, which is provided for receiving at least one storage medium, and wherein two mutually different carrier structures are configured separately from the housing element, and via which the storage housing is intended to be retained on a structure of the motor vehicle,
wherein a first of the design variants of the storage housing has the housing element and a first of the carrier structures, which in the first design variant is connected to the housing element, and
wherein a second design variant of the storage housing has the housing element and the second carrier structure, which in the second design variant is connected to the housing element.

12. The modular system according to claim 11,
wherein the respective carrier structure is in the form of a respective carrier frame.

13. The modular system according to claim 11,
wherein in the respective design variant, the housing element is received in the respective carrier structure.

14. The modular system according to claim 11,
wherein the housing element comprises two housing portions which are configured separately from each other and which are connected to each other.

15. The modular system according to claim 14,
wherein at least one of the housing portions is in the form of a shell.

16. The modular system according to claim 11,
wherein the housing element has at least one transverse strut which extends in the installation position of the housing element in the motor vehicle in the transverse vehicle direction of the motor vehicle.

17. The modular system according to claim 11,
wherein the housing element has at least one connection location, via which the housing element can be secured to the structure of the motor vehicle.

18. The modular system according to claim 11,
wherein in the respective design variant, the housing element and the respective carrier structure are adhesively bonded to each other.

19. The modular system according to claim 11,
wherein a third design variant of the storage housing which is different from the design variants has a second housing element which is different from the housing element and which at least partially delimits a second receiving space which is provided to receive the at least one storage medium, and has one of the carrier structures to which the second housing element is connected in the third design variant.

20. A method for producing at least two design variants of a storage housing which has a housing element and a carrier structure for an energy store for a motor vehicle, the method comprising:
providing a housing element which at least partially delimits a receiving space of the storage housing, which is provided to receive at least one storage medium, and
providing two carrier structures which are configured separately from the housing element and which are different from each other, and via which the storage housing is intended to be retained on a structure of the motor vehicle,
wherein, in order to produce a first of the design variants of the storage housing, the housing element and a first of the carrier structures, which in the first design variant is connected to the housing element, are provided, and
wherein, in order to produce the second design variant of the storage housing, the housing element and the second carrier structure, which in the second design variant is connected to the housing element, are provided.
